(19) United States
(12) Patent Application Publication
(10) Pub. No.: US 2013/0316133 A1
(43) Pub. Date: Nov. 28, 2013

(54) PROTECTIVE FILM FOR PORTABLE ELECTRONIC DEVICE USING REINFORCED GLASS

(71) Applicant: SPIGEN SGP KOREA, Seoul (KR)

(72) Inventor: Dae-Young KIM, Seoul (KR)

(73) Assignee: SPIGEN SGP KOREA, Seoul (KR)

(21) Appl. No.: 13/895,762

(22) Filed: May 16, 2013

(30) Foreign Application Priority Data
May 22, 2012 (KR) 10-2012-0054088

(51) Int. Cl. H05K 5/03; B32B 3/02

(52) U.S. Cl. CPC H05K 5/03; B32B 3/02
USPC 428/137

(57) ABSTRACT

A protective film for a portable electronic device using reinforced glass is provided. The protective film includes a through-hole formed in a size corresponding to any one of a speaker, a microphone, a button, and a camera provided on a surface having a display panel of the portable electronic device, a reinforced glass film made of reinforced glass, a polyethylene terephthalate (PET) layer formed on the lower surface of the reinforced glass film and made of PET, an adhesive layer for adhering the reinforced glass film and the PET layer, a tacky layer for tackifying the PET layer and the surface of the portable electronic device, and a cutting part formed by cutting each of angled portions along edges of the reinforced glass film and around the through-hole.

### PRIORITY

This application claims the benefit under 35 U.S.C. §119(a) of a Korean patent application filed on May 22, 2012 in the Korean Intellectual Property Office and assigned Serial No. 10-2012-0054088, the entire disclosure of which is hereby incorporated by reference

### BACKGROUND OF THE INVENTION

1. Field of the Invention

The present invention relates to a protective film for a portable electronic device using reinforced glass. More particularly, the present invention relates to a protective film using reinforced glass for protecting a display panel for a portable electronic device, wherein angled portions of a reinforced glass layer are cut so as to enhance resistance to external impact and to improve a grip feeling.

2. Description of the Related Art

Electronic devices which can be freely utilized while being portable in pockets, bags, etc. by users are referred to as portable electronic devices. Presently, examples of widely available portable electronic devices include mobile communication terminals (including smart phones), video players, MP3 players, game machines, etc. Such portable electronic devices are mainly configured such that a display panel is provided on the front surface thereof in order to represent media/contents such as video images, etc.

Particularly with the advancement of display panel techniques such as LCD, LED, OLED, etc., display panels have a tendency toward increasing in size in order to ensure sufficient viewing, and for sake of easy operation, these are manufactured in the form of a touch screen.

However, such display panels are weak to impact and may thus be broken or damaged when falling on the floor or by external impact, undesirably causing problems of high repair costs and disabled touch screen functions. Hence, with the goal of protecting such display panels, a protective film is widely used.

A protective film is provided to come into close contact with the display panel so as to exhibit impact absorption and anti-scratching functions. This film has been manufactured in the form of a film made of a synthetic resin for a typical thin film, and recently, a protective film using reinforced glass is being introduced.

In regard to a protective film using reinforced glass for mobile phones, etc., related techniques are disclosed in Korean Patent Nos. 1069642 and 630309, Korean Utility Model Application No. 20-2006-0069091, etc.

Specifically, Korean Patent No. 1069642 discloses a display protection film for a handy terminal, comprising a reinforced glass film, a printing layer, and a double-sided tape layer attached to the printing layer, wherein a transparent synthetic resin film is attached to the lower surface of the reinforced glass film by means of an adhesive layer, and the adhesive layer may include either a transparent acrylic adhesive or a transparent urethane-based adhesive such that the reinforced glass film and the transparent synthetic resin film to which a polyethylene terephthalate (PET) film will be applied are combined via hot pressing in order to increase light transmittance, and a hard coating layer on which the printing layer is provided is formed on the lower surface of the transparent synthetic resin film, thus ensuring high light transmittance, as well as impact absorption functions via the reinforced glass.

Reinforced glass, which has balanced force distribution therein, breaks into fragments in a size corresponding to a red bean when any portion thereof is cut off or crushed. In particular, in the case where external impact is applied not in a perpendicular direction but in a lateral or diagonal direction, there may occur problems of the reinforced glass film of the protective film being thrust to one side from the surface of the attached target or being broken, and furthermore, when a user grasps such a device, he or she feels discomfort due to hard angled portions of the reinforced glass.

According to the above technique, the use of the reinforced glass leads to superior light transmittance but causes the above problems, which have not yet been overcome.

Thus, there is a need to develop a novel and advanced protective film using reinforced glass, wherein superior properties with respect to external impact are fundamentally provided thanks to the use of reinforced glass, and the angled portions of the reinforced glass film are cut, thus exhibiting flexible response to external impact and a more natural grip feeling.

The above information is presented as background information only to assist with an understanding of the present disclosure. No determination has been made, and no assertion is made, as to whether any of the above might be applicable as prior art with regard to the present invention.

### SUMMARY OF THE INVENTION

Aspects of the present invention are to address at least the above-mentioned problems and/or disadvantages and to provide at least the advantages described below. Accordingly, an aspect of the present invention has been made keeping in mind the above problems encountered in the related art, and an object of the present invention is to provide a protective film wherein the angled portions of a reinforced glass film may be cut using chamfering, filleting or rounding treatment so as to increase safety against external impact and to improve a natural grip feeling.

Another aspect of the present invention is to provide a protective film which includes means for preventing a display target of a display panel from being distorted due to the action of reinforced glass as a convex lens or due to refraction of light upon cutting the angled portions of a reinforced glass film.

Another aspect of the present invention is to provide a protective film wherein an oleophobic coating layer is additionally applied on the reinforced glass film so as to prevent the surface of the reinforced glass film from staining with impurities.

Another aspect of the present invention is to provide a protective film wherein a cutting part may be processed in a variety of shapes so as to maximize advantages thereof.

Another aspect of the present invention is to provide a protective film wherein the surface of the cutting part is subjected to distortion prevention treatment so as to prevent distortion of a display target of a display panel due to refraction of light.

In accordance with an aspect of the present invention, a protective film for a portable electronic device is provided. The protective film, using reinforced glass, includes a through-hole formed in a size corresponding to any one of a speaker, a microphone, a button, and a camera provided on a surface having a display panel of the portable electronic device; a reinforced glass film comprising reinforced glass, a PET layer formed on a lower surface of the reinforced glass film and comprising PET, an adhesive layer for adhering the reinforced glass film and the PET layer, a tacky layer for tackifying the PET layer and a surface of the portable electronic device, and a cutting part formed by cutting each of angled portions along edges of the reinforced glass film and around the through-hole.

Also, an oleophobic coating layer may be additionally applied.

The cutting part may be provided in the form of either a chamfer part formed by chamfering each of the angled portions along the edges of the reinforced glass film and around the through-hole, or a round part formed by rounding each of the angled portions along edges of the reinforced glass film and around the through-hole.

Also, the cutting part may be provided in the form of a composite cutting part comprising rounded parts formed by rounding an upper surface and a lateral surface of the reinforced glass film corresponding to positions at which cutting begins, and a planar part formed by evenly cutting the round parts.

Also, the surface of the cutting part may be subjected to scratching treatment so as to be imparted with roughness such that a coefficient of friction thereof is greater than that of the surface of the reinforced glass film not subjected to scratching treatment.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments of the present invention will be more apparent from the following description taken in conjunction with the accompanying drawings, in which:

FIG. 1 is a perspective view illustrating a protective film according to an exemplary embodiment of the present invention, which is attached to the surface of a portable electronic device;

FIG. 2 is a cross-sectional view illustrating the stacking configuration of the protective film according to an exemplary embodiment of the present invention;

FIG. 3 is a view illustrating an oleophobic coating layer additionally applied on a reinforced glass film according to an exemplary embodiment of the present invention;

FIGS. 4A to 4C illustrate a cutting part according to an exemplary embodiment of the present invention; and

FIGS. 5A to 5C illustrate a distortion prevention part additionally formed on the surface of the cutting part according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the present invention, a portable electronic device indicates a mobile communication terminal (including a smart phone), a video/mp3 player, a game machine, etc. A target to which the protective film of the present invention is attached is a surface having a display panel of a portable electronic device, and in the appended drawings, a portable electronic device, in particular, a smart phone is exemplified.

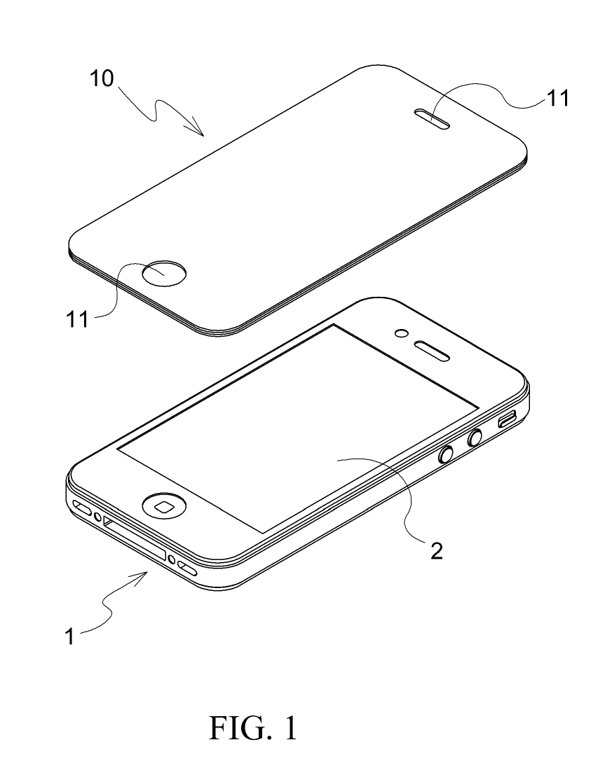

FIG. 1 is a perspective view illustrating a protective film according to an exemplary embodiment of the present invention, which is attached to the surface of a portable electronic device.

According to the present invention, the protective film 10 is attached to the surface having a display panel 2 of a portable electronic device 1. Currently, the surface having the display panel 2 of the portable electronic device 1 is mainly provided with not only the display panel 2 but also with an operation button, a speaker, a camera, a microphone, etc. In order to prevent the above targets from being covered with the protective film 10, through-holes 11 are formed in the protective film 10 so as to be adapted for sizes of the speaker, button, etc. that are different per manufacturer.

Specifically, because there are many cases where not only the display panel 2 but also a speaker, an operation button, a microphone, a camera, etc., are provided on the surface having the display panel 2 of the portable electronic device 1, the through-holes 11 are formed in the protective film 10 so as to correspond to the sizes of the above targets. Thereby, angled portions are formed along the edges of the reinforced glass film and around the through-holes 11, and such angled portions have to be cut so as to respond to external impact.

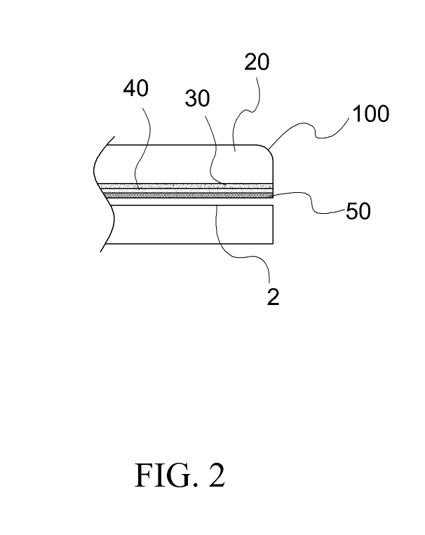

FIG. 2 is a cross-sectional view illustrating the stacking configuration of the protective film according to an exemplary embodiment of the present invention.

Referring to FIG. 2, the protective film 10 according to the present invention is transparent so as to exhibit fundamental functions in which display targets on the display panel of the portable electronic device are well shown, and impact absorption and anti-scratching functions.

Such a protective film 10 is configured such that a reinforced glass film 20, an adhesive layer 30, a polyethylene terephthalate (PET) layer 40, and a tacky layer 50 are sequentially formed downwards, and each of the angled portions of the reinforced glass film 20 is provided with a cutting part 100.

The reinforced glass film 20 according to the present invention is made of reinforced glass, in which the reinforced glass indicates glass which is reinforced by subjecting the surface to compression and the inside to tensioning, and has bending strength three to five times and impact resistance three to eight times as high as those of typical glass.

However, the case where impact is applied to the angled portions of reinforced glass having balanced force distribution therein is problematic because not only the angled portions but also the entire glass may break down.

Thus, an important feature of the protective film 10 according to the present invention is to provide a cutting part 100 formed by cutting each of the angled portions of the reinforced glass film 20 which constitutes the top and most portions of the protective film.

Referring FIG. 2, the cutting part 100 is provided at each of the angled portions of the reinforced glass film 20 along edges of the reinforced glass film 20 and around the through-holes 11, and is formed by cutting each of right-angled portions of the reinforced glass film 20.

The cutting part 100 is advantageous because the total force of the reinforced glass film 20 may be prevented from being unbalanced when any angled portion of the reinforced glass film 20 may break down by external impact applied in a direction of the angled portion, that is, force applied in a lateral or diagonal direction, and also because of solving problems of a user feeling discomfort due to the right-angled portions, and various exemplary embodiments thereof are described below.

The PET layer 40 of the present invention is disposed between the adhesive layer 30 and the tacky layer 50 under the reinforced glass film 20, and functions to prevent generation of foam when the reinforced glass film 20 is attached to the surface of the portable electronic device 1, and to prevent malfunctioning of a touch screen which is used as the display panel 2 of the portable electronic device 1.

The adhesive layer 30 plays a role in adhering the reinforced glass film 20 and the PET layer 40 to each other, and as necessary, while the adhesive layer 30 dissolves via heat treatment, the reinforced glass film 20 and the PET layer 40 may be bonded to each other.

The tacky layer 50 enables the PET layer 40 to be stably positioned in the protective film 10 according to the present invention and also the protective film 10 to be tackified (detachably attached) to the upper surface of the display panel 2 of the portable electronic device 1. Such a tacky layer 50 may include a variety of tackifiers, and preferably a silicone-based tackifier so as to enable mild tackifying without damage to the surface of the display panel 2 of the portable electronic device 1.

In such a configuration, the protective film 10 according to the present invention may exhibit enhanced impact resistance thanks to the use of the reinforced glass, and also may prevent the reinforced glass film 20 from breaking down even in the presence of force applied in a lateral or diagonal direction, and may increase a grip feeling of a user.

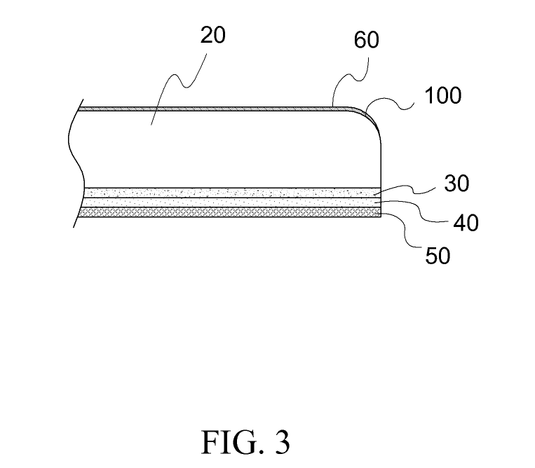

FIG. 3 illustrates an oleophobic coating layer additionally formed on the reinforced glass film according to an exemplary embodiment of the present invention.

The oleophobic coating layer 60 is formed by coating the upper surface of the reinforced glass film 20 with a coating material comprising an oleophobic composition, so as to prevent impurities from remaining behind on the surface of the reinforced glass film 20 by frequent touch of a user for operation of a touch screen.

Furthermore, the oleophobic coating layer 60 is applied on the surface of the cutting part 100 so as to protect the surface of the cutting part 100, and is preferably applied up to the end (tip) of the cutting part 100.

Such an oleophobic coating layer 60 may include a known hydrophilic surfactant composition, and the specific composition of the oleophobic coating layer 60 having oleophobic properties is based on a known composition, and thus an additional description thereof is omitted.

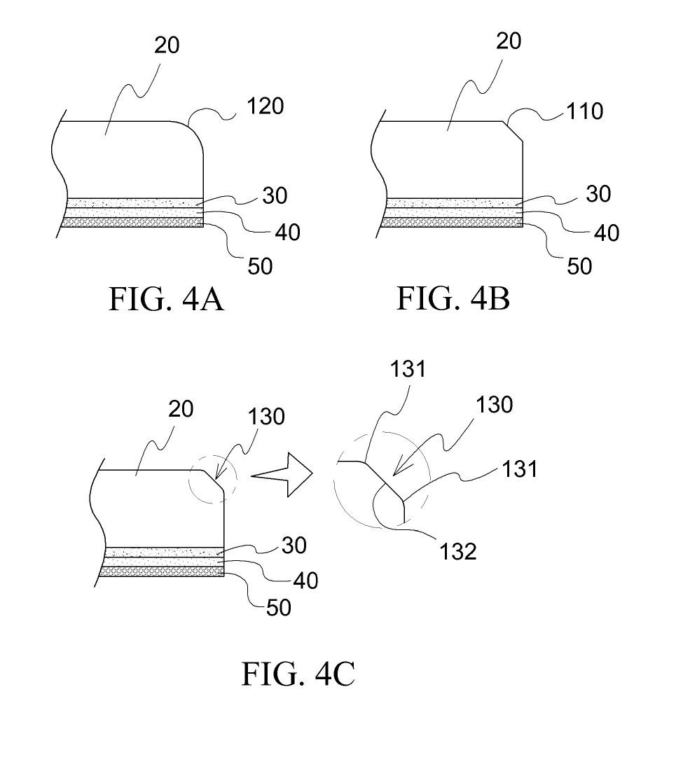

FIGS. 4A to 4C illustrate a variety of modifications of the cutting part according to an exemplary embodiment of the present invention.

According to a first exemplary embodiment, the cutting part 100 is provided in the form of a chamfer part 110 obtained by chamfering an angled portion of the reinforced glass film.

Referring to FIG. 4A, the chamfer part 110 is formed by obliquely cutting the angled portion, thus facilitating the cutting process, and reducing the angle of a right-angled portion of the reinforced glass film 20 before a cutting process, ultimately imparting resistance to external impact and an improved grip feeling by the cutting part 100 as desired in the present invention.

According to a second exemplary embodiment, the cutting part 100 is provided in the form of a round part 120 by subjecting an angled portion of the reinforced glass film 20 to rounding treatment.

Referring to FIG. 4B, unlike the chamfer part 110, the round part 120 is formed via smooth rounding treatment of the angled portion of the reinforced glass film 20 without generation of any angle, thus more appropriately responding to external impact and improving a grip feeling.

According to a third exemplary embodiment, the cutting part 100 is provided in the form of a composite cutting part 130 in combination of the chamfer part 110 and the round part 120, and the composite cutting part 130 includes rounded parts 131 formed by performing rounding treatment of the upper surface and the lateral surface of the reinforced glass film corresponding to the positions at which cutting begins, and a planar part 132 by evenly cutting the rounded parts 131.

Referring to FIG. 4C, the composite cutting part 130 is formed by rounding the edges at which cutting begins thus forming two rounded parts which are then evenly cut to be connected.

When the composite cutting part 130 is formed in this way, the generation of the angle in the chamfer part 110 may be eliminated, and also the extent of upward protrusion in the round part 120 may be minimized, thus preventing the protrusion portion from being exposed to external impact. Furthermore, because the round part 120 may function as a convex lens, problems in which the display target of the display panel 2 appears to be larger when the user's gaze rests on the round part may be prevented as much as possible.

That is, there is the potential for causing problems in which the display target of the display panel 2 is distorted or appears to be larger due to refraction of light by the cutting part 100, and thus this exemplary embodiment is intended to maintain the target of the display panel 2 as it is or minimize the distortion thereof in order to reduce the generation of the above problems.

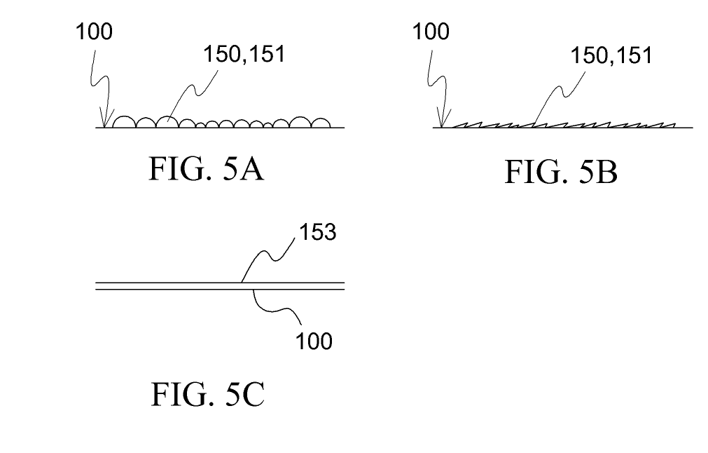

FIGS. 5A to 5C illustrate a distortion prevention part which is additionally formed on the surface of the cutting part according to an exemplary embodiment of the present invention.

As mentioned above, even if the cutting part 100 formed by cutting the angled portion of the reinforced glass film 20 is in a very small size, problems may occur in which the display target of the display panel 2 may be distorted due to refraction of light.

Although the above problems may be minimized by means of the composite cutting part 130, in order to basically solve them, the distortion prevention part is additionally provided so that the surface of the cutting part 100 is treated so as to prevent light from passing therethrough or is imparted with roughness to thereby block flow of light.

The distortion prevention portion 150 according to the present invention is used to prevent distortion or refraction of light due to transmission of light into the reinforced glass film 20 through the surface of the cutting part 100. In the most feasible exemplary embodiment, the surface of the cutting part 100 is treated to be black so as to absorb light. In this case, however, an unnatural and awkward appearance of the reinforced glass film 20 may result, and thus it is preferred that the surface of the cutting part 100 be treated with the distortion prevention portion 150.

In a first exemplary embodiment, the distortion prevention portion 150 is provided by forming a plurality of protrusions 151 in a small size on the surface of the cutting part 100.

Referring to FIG. 5A, the distortion prevention portion 150 is configured such that the plurality of protrusions 151, which induce diffused reflection of light, overlap with each other or are continuously arranged, whereby light is reflected to the outside, consequently preventing a screen displayed on the display panel 2 from being distorted due to the cutting part 100.

In a second exemplary embodiment, the distortion prevention portion 150 is provided by subjecting the surface of the cutting part 100 to scratching treatment to impart roughness so that a coefficient of friction thereof is greater than that of the surface of the reinforced glass film 20 not subjected to scratching treatment.

Referring to FIG. 5B, the surface of the cutting part 100 is roughened so as to become opaque while showing a similar appearance, thereby preventing the screen displayed on the display panel 2 from being distorted due to refraction of light through the surface of the cutting part 100.

In a third exemplary embodiment, the distortion prevention portion 150 is provided by additionally forming an anti-reflective coating layer 153 on the surface of the cutting part 100.

The anti-reflective coating is mainly utilized in the optical field such as lenses or spectacles, hardware such as display devices, etc. The most preferred exemplary embodiment for anti-reflection is to blacken the surface of the cutting part 100 in order to prevent reflection and to absorb light, as mentioned above. In this case, however, only the surface of the cutting part 100 is blackened and thus exhibits a poor appearance. Hence, it is more preferable that the anti-reflective coating layer 153 be additionally applied to prevent the display target of the display panel 2 from being distorted through the surface of the cutting part 100, which is illustrated in FIG. 5C.

The anti-reflective coating layer 153 may be formed of a variety of known materials including metals or polymer synthetic resins. The anti-reflective coating layer 153 according to the present invention is manufactured using such a known material, and thus a description of additional properties or composition thereof is omitted.

Such an anti-reflective coating layer 153 is applied on the surface of the cutting part in such a manner that the thickness thereof is decreased toward the end of the surface of the cutting part 100 so as to not generate any angle or step height.

As described hereinbefore, the present invention provides a protective film for a portable electronic device using reinforced glass. According to the present invention, the protective film can exhibit the following effects: 1) the use of a reinforced glass film can increase durability, and also angled portions thereof which are weak to impact are cut, thus increasing resistance to external impact and a grip feeling; 2) a cutting part can be processed in various shapes so as to not protrude, thus enhancing fine durability; 3) the surface of the cutting part is subjected to distortion prevention treatment, thus preventing distortion of a target displayed on the display panel; and 4) the use of an oleophobic film can prevent oil components from remaining behind on the reinforced glass film.

While the invention has been shown and described with reference to certain exemplary embodiments thereof, it will be understood by those skilled in the art that various changes in form and details may be made therein without departing from the scope and spirit of the invention as defined by the appended claims and their equivalents.

What is claimed is:

1. A protective film for a portable electronic device using reinforced glass, the protective film comprising:
a through-hole formed to expose each of a button, a speaker, or a camera of the portable electronic device;
a reinforced glass film comprising reinforced glass;
a polyethylene terephthalate (PET) layer formed on a lower surface of the reinforced glass film and comprising PET;
an adhesive layer for adhering the reinforced glass film and the PET layer;
a tacky layer for tackifying the PET layer and a surface of the portable electronic device; and
a cutting part formed by cutting each of angled portions along edges of the reinforced glass film and around the through-hole,
wherein the through-hole is formed in the reinforced glass film, the PET layer, the adhesive layer and the tacky layer and has a size corresponding to any one of the speaker, a microphone, the button, and the camera provided on a surface having a display panel of the portable electronic device.

2. The protective film of claim 1, further comprising an oleophobic coating layer formed on an upper surface of the reinforced glass film.

3. The protective film of claim 1, wherein the cutting part is provided in a form of either a chamfer part formed by obliquely cutting each of the angled portions along the edges of the reinforced glass film and around the through-hole, or a round part formed by rounding each of the angled portions along the edges of the reinforced glass film and around the through-hole.

4. The protective film of claim 1, wherein the cutting part is provided in a form of a composite cutting part comprising rounded parts formed by rounding an upper surface and a lateral surface of the reinforced glass film corresponding to positions at which cutting begins, and a planar part formed by evenly cutting the round parts.

5. The protective film of claim 1, wherein a surface of the cutting part is imparted with a plurality of protrusions.

6. The protective film of claim 1, wherein a surface of the cutting part is subjected to scratching treatment so as to be imparted with roughness such that a coefficient of friction thereof is greater than that of the surface of the reinforced glass film not subjected to scratching treatment.

7. The protective film of claim 1, wherein a surface of the cutting part is further coated with an anti-reflective coating layer.
